(19) United States
(12) Patent Application Publication
(10) Pub. No.: US 2001/0004330 A1
(43) Pub. Date: Jun. 21, 2001

(54) Non-volatile semiconductor memory device and manufacturing method thereof

(75) Inventors: Seung-woo Nam, Yongin-city (KR); Jung-dal Choi, Suwon-city (KR)

Correspondence Address: Steven M. Mills, Esq., Samuels, Gauthier & Stevens LLP, 225 Franklin Street, Boston, MA, 02110, US

(73) Assignee: Samsung Electronics Co., Ltd.

(21) Appl. No.: 09/740,512

(22) Filed: Dec. 19, 2000

(30) Foreign Application Priority Data
Dec. 21, 1999 (KR) 99-59854

(51) Int. Cl. G11C 7/00

(52) U.S. Cl. 365/200; 438/258; 257/321

(57) ABSTRACT

A non-volatile semiconductor memory device and a method for making the device are described. The device has a memory cell array region including a cell transistor capable of storing and erasing data and a peripheral circuit region including a transistor for driving the memory cell array region. The cell transistor includes a stacked gate pattern in which a floating gate, an interlayer insulating layer and a control gate are sequentially provided over a semiconductor substrate underlying a tunnel insulating layer. A source/drain region of a single diffused structure having a first impurity region is aligned along the sidewalls of the stacked gate pattern and formed in the vicinity of the surface of the semiconductor substrate. Alternatively, the cell transistor includes a source/drain region of a double diffused structure further having a fourth impurity region which is deep doped with impurities of a higher concentration than the that of the first impurity region. On the other hand, the transistor of the peripheral circuit region includes a gate insulating layer and a gate electrode overlying a semiconductor substrate, spacers formed along the sidewalls of the gate electrode, and a source/drain region of a lightly doped drain structure having a second impurity region which is aligned along the sidewalls of the gate electrode and formed in the vicinity of the surface of the semiconductor substrate and a third impurity region which is aligned with the spacers and deep doped with impurities of a higher concentration than that of the second impurity region. In the non-volatile semiconductor memory device, since the spacers are formed only on the peripheral circuit region, a field insulating layer formed on a memory cell array region is not overetched, so that the insulation characteristic between unit devices can be improved.

### BACKGROUND OF THE INVENTION

1. Field of the Invention

The present invention relates to a semiconductor memory device and manufacturing method thereof and more particularly to a non-volatile semiconductor memory device and manufacturing method thereof.

2. Description of the Related Art

In recent years, much attention has been directed to non-volatile semiconductor memory devices, such as a flash semiconductor memory devices, in which all data can be erased simultaneously. Non-volatile semiconductor memory devices, which are used, for example, as storage devices in computer cards, cameras, or the like, can not only erase and store data electrically, but can also retain the data when power is removed.

In order to utilize such a non-volatile semiconductor memory device as a storage device, high integration density is essential. As non-volatile semiconductor memory devices become more densely integrated, the area occupied by transistors of memory cell arrays and peripheral circuit regions is reduced. Such reduction in the area of transistors may induce a short-channel effect which weakens the breakdown characteristic of transistors.

FIGS. 1 and 2 are partial plan views of memory cell array and peripheral circuit regions in a general non-volatile semiconductor memory device, respectively. Specifically, in the memory cell array region of FIG. 1, a floating gate and a word line which serves as a control gate are referred to as reference numerals 3 and 5, respectively. In the peripheral circuit region of FIG. 2, a word line which acts as a gate electrode is referred to as reference numeral 7. In FIGS. 1 and 2, reference numeral 9 denotes an active region and the remaining regions are a field region in which a field insulating layer is formed.

FIGS. 3A, 4A, 5A, 6A, 7A and 8A are schematic sectional views of a conventional non-volatile semiconductor memory device taken along line a-a of FIG. 1. FIGS. 3B, 4B, 5B, 6B, 7B and 8B are schematic sectional views of a conventional non-volatile semiconductor memory device taken along line b-b of FIG. 1. FIGS. 3C, 4C, 5C, 6C, 7C and 8C are schematic sectional views of a conventional non-volatile semiconductor memory device taken along line c-c of FIG. 2. These figures are used herein to describe a method of manufacturing the semiconductor device.

Referring to FIGS. 3A-3C, a field insulating layer 13 is formed over a semiconductor substrate 11 to define an active region 9, and a tunnel insulating layer 17 is provided over the semiconductor substrate 11 on which a memory cell array region is to be formed. Subsequently, after forming a polysilicon layer atop the tunnel insulating layer 17 of the memory cell array region, a first polysilicon pattern 19a is formed in the a-a direction (in the active region direction shown in FIG. 1) by patterning the polysilicon layer. An oxide-nitride-oxide (ONO) layer 21 overlies the semiconductor substrate 11 over which the first polysilicon pattern 19a of the memory cell array region is formed, and after eliminating an ONO layer which has been formed over the peripheral circuit region, a gate insulating layer 18 is provided on the peripheral circuit region. Then, a second polysilicon layer 23 and a tungsten silicide layer 25 are formed sequentially over the ONO layer 21 of the memory cell array region and the gate insulating layer 18 of the peripheral region circuit region, respectively.

Referring to FIGS. 4A-4C, a first photoresist pattern 27 which covers the peripheral circuit region as shown in FIG. 4C and exposes a portion of the memory cell array region as shown in FIGS. 4A and 4B is formed. Then, the tungsten silicide layer 25, the second polysilicon layer 23, the ONO layer 21, and the first polysilicon pattern 19a are sequentially etched using the first photoresist pattern 27 as an etching mask. As a result, a control gate 29 including a tungsten silicide pattern 25a and a second polysilicon pattern 23a, an interlayer insulating layer 21a, and a floating gate 19b are stacked sequentially to form a stacked gate pattern 29, 21a and 19b.

During an etching process for forming the stacked gate pattern 29, 21a and 19b of FIG. 4A, it is necessary to perform an overetch to remove the ONO layer 21 formed along the sidewalls of the first polysilicon pattern 19a of FIG. 3B. Thus, as shown in FIG. 4B the central portion of the field insulating layer 13 is etched and thinned by the thickness of the first polysilicon pattern 19a corresponding to that indicated by reference numeral 20.

Referring to FIGS. 5A-5C, after the first photoresist pattern 27 is removed, a second photoresist pattern 31 which covers the memory cell array region as shown in FIGS. 5A and 5B and which exposes some portions of the peripheral circuit region as shown in FIG. 5C is formed. Subsequently, the tungsten silicide layer 25 and the second polysilicon layer 23 are etched sequentially to form a gate electrode 33 comprised of a tungsten silicide pattern 25b and a second polysilicon pattern 23b.

Referring to 6A-6C, after the second photoresist pattern 31 is removed, impurities 34 such as phosphorus (P) are implanted over the entire surfaces of the memory cell array region over which the stacked gate pattern 29, 21a, and 19b is provided and the peripheral circuit region over which the gate electrode 33 is provided to thereby form a first impurity region 35. Referring to FIGS. 7A-7C, an insulating layer 37 is formed over the entire surfaces of the memory cell array and the peripheral circuit regions over which the stacked gate pattern 29, 21a and 19b and the gate electrode 33 are each disposed. Referring to FIGS. 8A-8C, the insulating layer 37 undergoes anisotropic etching to thereby form spacers 39 along the sidewalls of the stacked gate pattern 29, 21a and 19b and the gate electrode 33, which compensates for reduction in an effective channel length caused by high integration. Next, impurities 38 such as phosphorus (P) are implanted over the entire surfaces of the stackeed gate pattern 29, 21a and 19b and the gate electrode 33 along which the spacers 39 are disposed, with concentration and energy higher than that required in forming the first impurity region 35, thus forming a second impurity region 41.

As a result, the conventional non-volatile semiconductor memory device forms a source/drain region with the shallow doped first impurity region 35 and the second impurity region 41 on the memory cell array and the peripheral circuit regions. That is, the conventional memory device has a lightly doped drain (LDD) source/drain structure on the memory cell array and peripheral circuit regions. However, a conventional non-volatile semiconductor memory device manufacturing method for suppressing a short-channel effect has problems in the following aspects. Firstly, during dry etching to form the spacers shown in FIGS. 8A-8C, the central portion of the field insulating layer 13 which is overetched to the extent indicated by reference numeral 20 of FIG. 4B is overetched further as indicated by reference numeral 40 of FIG. 8B. Accordingly, the thickness of the field insulating layer 13 of FIG. 8B disposed between the word lines is significantly reduced, so that the electrical insulation between unit devices cannot be provided. Secondly, if the thickness of the field insulating layer 13 is reduced as shown in FIG. 8B, during ion implantation to form the second impurity region 41 the impurities 38 may permeate into the lower part of the field insulating layer 13 to cause occurrence of an electrical short between the active regions, which results in failure in operating the semiconductor device.

### SUMMARY OF THE INVENTION

To solve the above problems, it is an object of the present invention to provide a non-volatile semiconductor memory device having a field insulating layer which is not excessively overetched.

It is another object of the present invention to provide a method for manufacturing a non-volatile semiconductor memory device.

In accordance with the invention, there is provided a non-volatile semiconductor memory device having a memory cell array region including a cell transistor capable of storing and erasing data and a peripheral circuit region including a transistor for driving the memory cell array region. In particular, the cell transistor includes a stacked gate pattern in which a floating gate, an interlayer insulating layer and a control gate are sequentially provided over a semiconductor substrate underlying a tunnel insulating layer and a source/drain region of a single diffused structure including a first impurity region which is aligned along the sidewalls of the stacked gate pattern and formed in the vicinity of the surface of the semiconductor substrate. The transistor of the peripheral circuit region includes a gate insulating layer and a gate electrode overlying a semiconductor substrate, spacers formed along the sidewalls of the gate electrode, and a source/drain region of a lightly doped drain structure including a second impurity region which is aligned along the sidewalls of the gate electrode and formed in the vicinity of the surface of the semiconductor substrate and a third impurity region which is aligned on the spacers and deep doped with impurities of a concentration higher than that of the second impurity region.

In one embodiment, the spacers include an oxide layer. In an alternative embodiment, the spacers include a nitride layer.

In one embodiment, the cell transistor includes a source/drain region of a double diffused structure further including a fourth impurity region which is deep doped with impurities of a higher concentration than that of the first impurity region.

In another aspect, the invention is directed to a method of manufacturing a non-volatile semiconductor memory device. A tunnel insulating layer is formed on a memory cell array region of a semiconductor substrate over which a field insulating layer has been provided. A first conductive layer pattern is formed on the tunnel insulating layer and the field insulating layer, and an insulating layer is formed over the first conductive layer pattern. A gate insulating layer is formed over the semiconductor substrate of the peripheral circuit region, and a second conductive layer is formed on the insulating layer and the gate insulating layer. The second conductive layer of the peripheral circuit region is patterned to form a gate electrode. A first impurity region is formed to be aligned on the sidewalls of the gate electrode, in the vicinity of the surface of the semiconductor substrate. Spacers are formed along the sidewalls of the gate electrode in the peripheral circuit region. The second conductive layer, the insulating layer and the first conductive layer pattern of the memory cell array region are patterned to form a stacked gate pattern in which a floating gate, an interlayer insulating layer, and a control gate are sequentially stacked. A second impurity region which is aligned on the sidewalls of the stacked gate pattern is formed in the vicinity of the surface of the semiconductor substrate to form a source/drain region of a single diffused structure. A third impurity region which is aligned with the spacers of the peripheral circuit region and deep doped with impurities of a higher concentration than that of the first impurity region is provided to form a source/drain region of a lightly doped drain structure.

In one embodiment of the method, a fourth impurity region which is deep doped with impurities of a higher concentration than that of the second impurity region of the memory cell array region is also formed. Alternatively, the fourth impurity region may be formed with the same impurities and concentration as the third impurity region. Furthermore, the third impurity region may be formed with the same impurities and concentration as the second impurity region. The tunnel insulating layer and the gate insulating layer can be formed of an oxide layer or a composite layer of oxide and nitride layers. The spacer can be formed of an oxide layer or a nitride layer.

In another aspect, the invention is directed to another method of manufacturing a non-volatile semiconductor memory device. According the this method, a tunnel insulating layer and a first conductive layer are formed sequentially on memory cell array and peripheral circuit regions of a semiconductor substrate over which a field insulating layer has been provided. The first conductive layer is patterned to form a first conductive layer pattern over the tunnel insulating layer and the field insulating layer of the memory cell array region. An insulating layer is formed over the first conductive layer pattern, and a gate insulating layer is formed over the semiconductor substrate of the peripheral circuit region. A second conductive layer is formed over the insulating layer and gate insulating layer. The second conductive layer of the peripheral circuit region is patterned to form a gate electrode. A first impurity region is formed to be aligned along the sidewalls of the gate electrode, in the vicinity of the surface of the semiconductor substrate. Spacers are formed along the sidewalls of the gate electrode of the peripheral circuit region. The second conductive layer, the insulating layer and the first conductive layer pattern of the memory cell array region are patterned to form a stacked gate pattern in which a floating gate, an interlayer insulating layer and a control gate are sequentially stacked. A second impurity region aligned along the sidewalls of the stacked gate pattern is formed in the vicinity of the surface of the semiconductor substrate to form a source/drain region of a single diffused structure. A third impurity region which is aligned with the spacers of the peripheral circuit region and deep doped with impurities of a higher concentration than that of the first impurity region is provided to form a source/drain region of a lightly doped drain structure.

In one embodiment, a fourth impurity region, which is deeply doped with impurities of a higher concentration than the second impurity region of the memory cell array region, may be further formed. Alternatively, the fourth impurity region may be formed with the same impurities and concentration as the third impurity region. Furthermore, the third impurity region may be formed with the same impurities and concentration as the second impurity region.

The non-volatile semiconductor memory device according to the present invention forms spacers only in a peripheral circuit region, so that a field insulating layer of a memory cell array region cannot be overetched during dry etching for spacer formation. Accordingly, the insulation characteristic between unit devices can be improved.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIGS. 1 and 2 are schematic partial plan views of memory cell array and peripheral circuit regions, respectively, in a general non-volatile semiconductor memory device.

FIGS. 3A, 4A, 5A, 6A, 7A and 8A are schematic sectional views of a conventional non-volatile semiconductor memory device taken along line a-a of FIG. 1.

FIGS. 3B, 4B, 5B, 6B, 7B and 8B are schematic sectional views of a conventional non-volatile semiconductor memory device taken along line b-b of FIG. 1.

FIGS. 3C, 4C, 5C, 6C, 7C and 8C are schematic sectional views of a conventional non-volatile semiconductor memory device taken along line c-c of FIG. 2.

FIGS. 9A and 9B are schematic sectional views of a non-volatile semiconductor memory device according to the present invention taken along lines a-a and b-b of FIG. 1.

FIG. 9C is a schematic sectional view of a non-volatile semiconductor memory device according to the present invention taken along line c-c of FIG. 2.

FIGS. 10A, 11A, 12A, 13A, 14A and 15A are schematic sectional views of a non-volatile semiconductor memory device according to the present invention taken along lines a-a of FIG. 1.

FIGS. 10B, 11B, 12B, 13B, 14B and 15B are schematic sectional views of a non-volatile semiconductor memory device according to the present invention taken along lines b-b of FIG. 1.

FIGS. 10C, 11C, 12C, 13C, 14C and 15C are schematic sectional views of a non-volatile semiconductor memory device according to the present invention taken along lines c-c of FIG. 2.

### DETAILED DESCRIPTION OF PREFERRED EMBODIMENTS

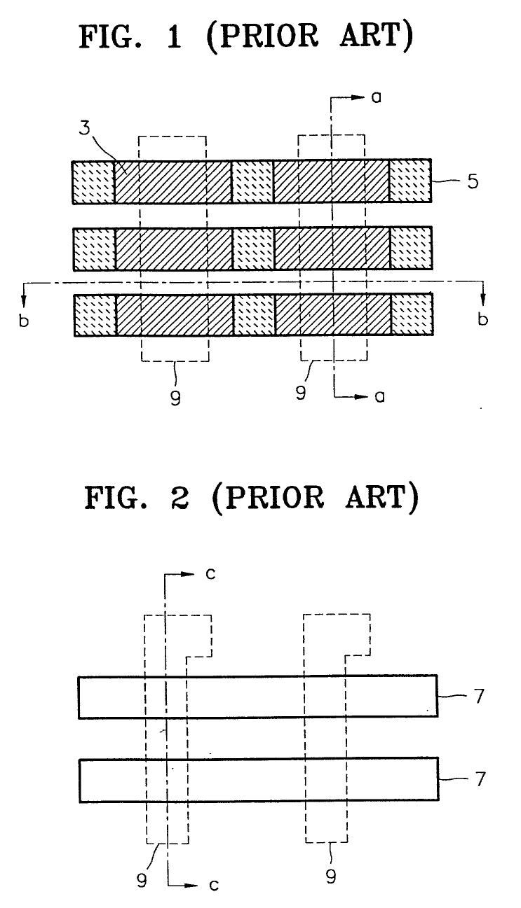

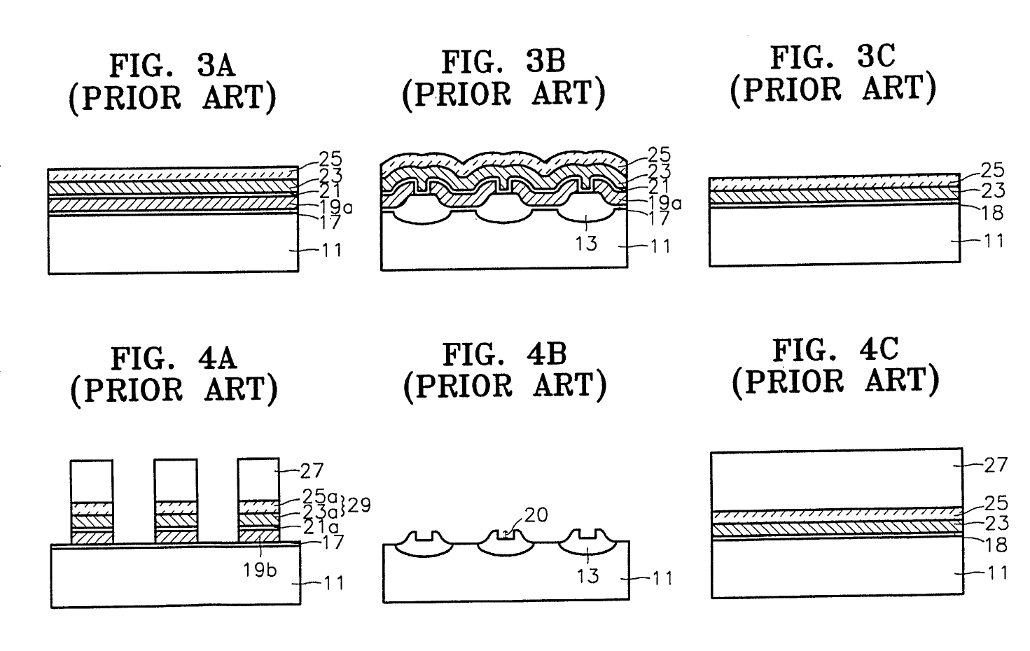

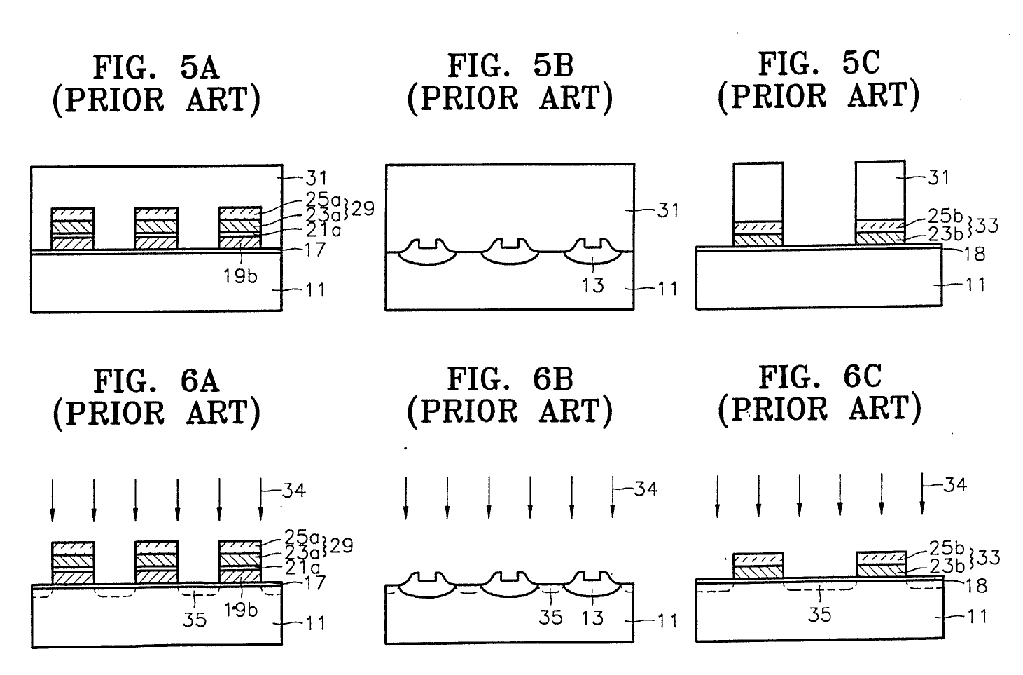

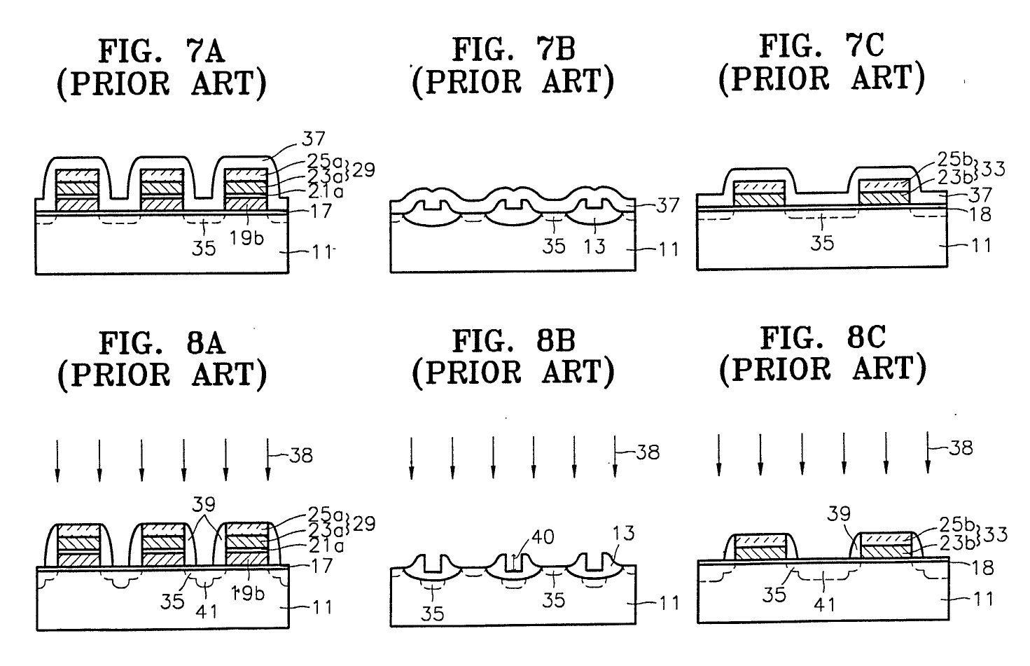

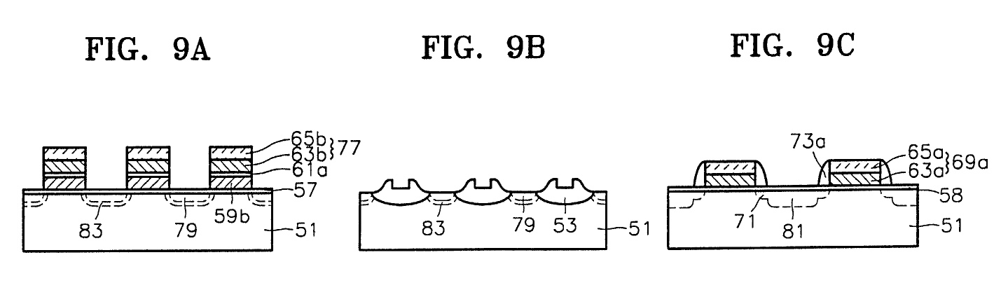

The plan views of a non-volatile semiconductor memory device according to the present invention are the same as FIGS. 1 and 2. Therefore, the present invention will be described with reference to drawings including FIGS. 1 and 2. FIGS. 9A and 9B are sectional views of a non-volatile semiconductor memory device according to the present invention taken along lines a-a and b-b, respectively, of FIG. 1, and FIG. 9C is a sectional view of a non-volatile semiconductor memory device according to the present invention taken along line c-c of FIG. 2.

A non-volatile semiconductor memory device according to the present invention is divided into two regions. A memory cell array region includes a cell transistor for storing and erasing data, and a peripheral circuit region includes a transistor for driving the memory cell array region. Specifically, as shown in FIG. 9A the memory cell array region includes a stacked gate pattern 59b, 61a and 77 in which a floating gate 59b, an interlayer insulating layer 61a and a control gate 77 are sequentially stacked on a tunnel insulating layer 57 overlying a semiconductor substrate 51. The control gate 77 is comprised of a polysilicon pattern 63b and a silicide pattern 65b. In particular, the memory cell array region is different from a conventional one in the aspects that no spacer is formed along the sidewalls of the stacked gate pattern 59b, 61a and 77, and a source/drain region is formed with a double diffused (DD) structure including a second impurity region 79 and a fourth impurity region 83 which is deep doped with impurities of a higher concentration than the second impurity region 79. Although the source/drain region are formed with the DD structure in FIGS. 9A and 9B, a single diffused (SD) structure can be utilized if only one of second and fourth impurity regions is formed. Further, as described below, the central portion of a field insulating layer 53 is formed thicker than a conventional one shown in FIG. 8B, which can alleviate problems respecting the insulation characteristic between unit devices and occurrence of electrical shorts as described above.

The peripheral circuit region, as shown in FIG. 9C, includes a gate insulating layer 58 and a gate electrode 69a overlying a semiconductor substrate 51, and a spacer 73a formed along the sidewalls of the gate electrode 69a. Especially in the peripheral circuit region, spacers are formed therein, and a source/drain region is formed with a shallow doped first impurity region 71 and a deep doped third impurity region 81. That is, the peripheral circuit region has a lightly doped drain (LDD) source/drain structure.

### FIRST EMBODIMENT

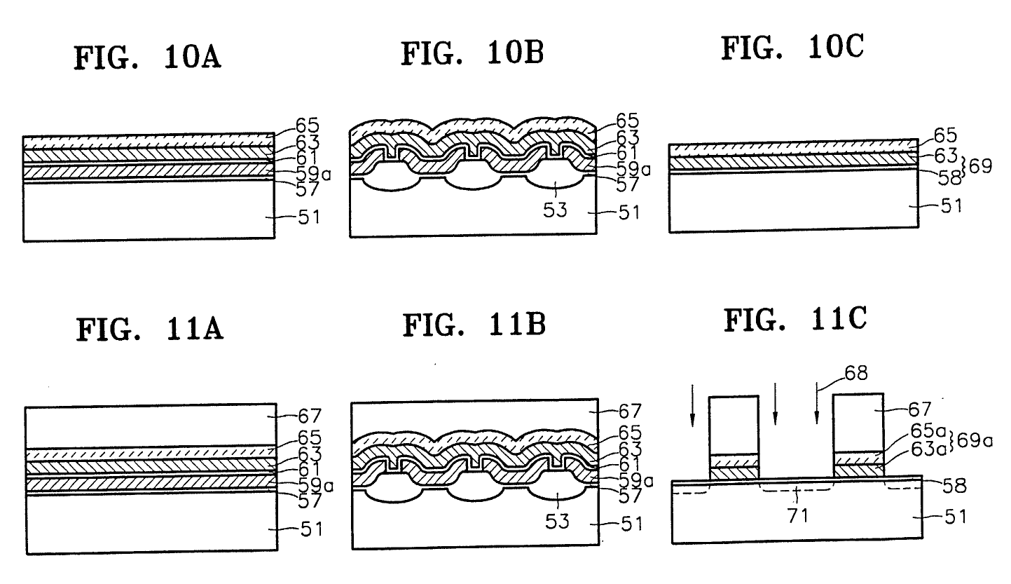

FIGS. 10A-15A, 10B-15B, and 10C-15C are each sectional views of a nonvolatile semiconductor memory device according to the present invention taken along lines a-a and b-b of FIG. 1 and c-c of FIG. 2, for illustrating a first embodiment of the manufacturing method thereof. Referring to FIGS. 10A-10C, a field insulating layer 53 is deposited over a semiconductor substrate 51 to define an active region. Subsequently, a tunnel insulating layer 57 having a thickness of 50-100 Å is formed over the semiconductor substrate 51 of a memory cell array region. The tunnel insulating layer 57 is formed of an oxide layer or a composite layer including oxide and nitride layers. Then, a first conductive layer (not shown) having a thickness of 1,000-1,500 Å such as a polysilicon layer with which group V impurities such as As or P are doped, is provided over the entire surface of the semiconductor substrate 51 on top of which the tunnel insulating layer 57 of the memory cell array region has been formed, and patterned to form a first conductive layer pattern 59a in the a-a direction (in the active region direction of FIG. 1). In this case, the first conductive layer formed on a peripheral circuit region is etched and removed.

Subsequently, a first insulating layer 61 such as oxide-nitride-oxide (ONO) film is formed over the entire surface of the semiconductor substrate 51 including the first conductive pattern 59a of the memory cell array region. Then, a gate insulating layer 58 having a thickness of 100-300 Å is formed over the peripheral circuit region from which the first insulating layer 61 has been removed. The gate insulating layer 58 is formed of an oxide layer or a composite layer including oxide and nitride layers. Thereafter, a second conductive layer 69 such as a second polysilicon layer 63 of 1,000-1,500 Å with which group V impurities are doped and a silicide layer 65 of 1,000-1,500 Å such as tungsten silicide layer are formed on top of the first insulating layer 61 of the memory cell array region and the gate insulating layer 58 of the peripheral circuit region, respectively.

Referring to FIGS. 11A-11C, a first photoresist pattern 67 which covers the memory cell array region as shown in FIGS. 11A and 11B and partially exposes the peripheral circuit region as shown in FIG. 11C is formed, and subsequently the second conductive layer 69 of the peripheral circuit region is etched using the first photoresist pattern 67 as an etching mask to form a gate electrode 69a comprised of a silicide pattern 65a and a second polysilicon pattern 63a. Continuously, using the first photoresist pattern 67 as a mask, group V impurities 68 such as phosphorous (P) and arsenic (As) are implanted at a dose of 1.0E13-3.0-E13 ions/cm² and at an energy of 30-50 KeV over the entire surface of the peripheral circuit region to form a first impurity region 71 in the vicinity of the surface of the semiconductor substrate 51.

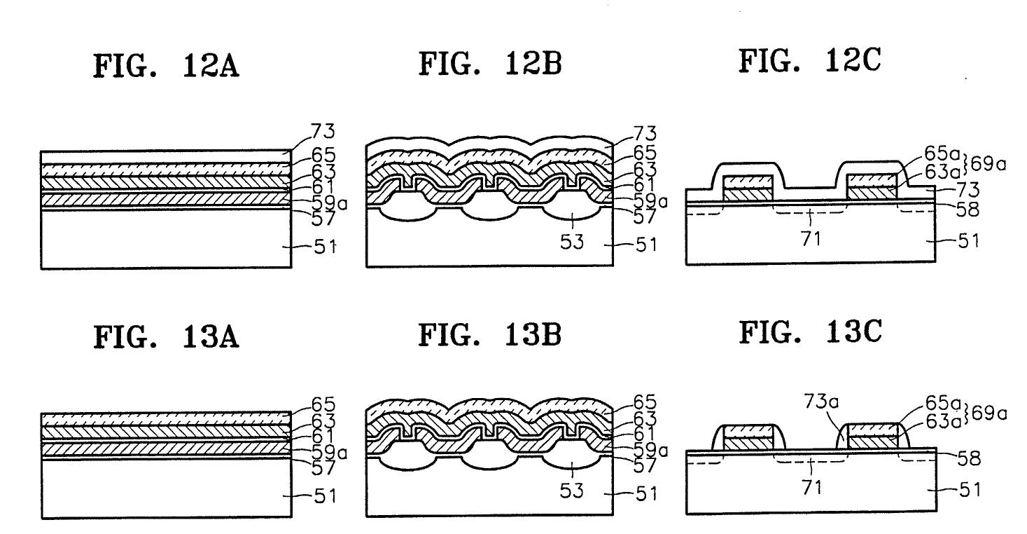

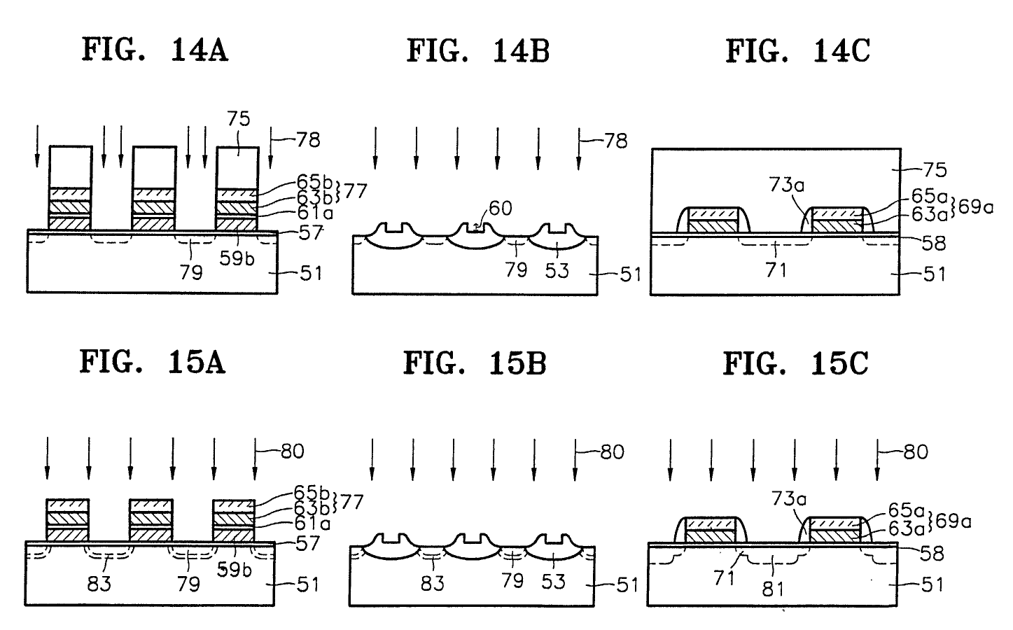

Referring to FIGS. 12A-12C, following removal of the first photoresist pattern 67, a second insulating layer 73, for example, oxide or nitride layer having a thickness of 1,000-2,000 Å, is formed over the entire surfaces of the memory cell array region and the peripheral circuit region on which the gate electrode 69a has been formed. Referring to FIGS. 13A-13C, the second insulating layer 73 undergoes anisotropic etching to form spacers 73a along the sidewalls of the gate electrode 69a of the peripheral circuit region. In this case, since the silicide layer 65, the second polysilicon layer 63, the first insulating layer 61, and the first conductive layer pattern 59a are provided on the memory cell array region of FIGS. 13A and 13B, the field insulating layer 53 dos not suffer a damage, differently from a prior art. Referring to FIGS. 14A-14C, a second photoresist pattern 75 which covers the peripheral circuit region as shown in FIG. 14C and partially exposes the memory cell array region as shown in FIG. 14A is provided. Subsequently, the silicide layer 65, the second polysilicon layer 63, the first insulating layer 61 and the first conductive layer pattern 59a are sequentially etched using the second photoresist pattern 75 as an etching mask to thereby form a stacked gate pattern 77, 61a and 59b which is sequentially stacked with a control gate 77 comprised of a silicide pattern 65b and a second polysilicon pattern 63b, an interlayer insulating layer 61a and a floating gate 59b. During etching process for forming the stacked gate pattern 77, 61a and 59b of FIG. 14A, it is necessary to perform an overetch for removing the first insulating layer 61, i.e., ONO layer which is formed along the sidewalls of the first conductive pattern 59a as shown in FIG. 13B. As a result, the central portion of the field insulating layer 53 becomes thinner as indicated by reference numeral 60.

Then, using the second photoresist pattern 75 as a mask, impurities 78 such as phosphorous (P) and arsenic (As) are implanted at a dose of 5.0E12-5.0E13 ions/cm² and at an energy of 30-50 KeV over the entire surface of the memory cell array region to form a second impurity region 79 thereon. In this case, the steps of forming the second photoresist pattern 75 and implanting impurities for forming the second impurity region 79 of the memory cell array region can be omitted. Referring to FIG. 15A-15C, after removing the second photoresist pattern 75, impurities 80 are implanted over the entire surfaces of the peripheral circuit region on which the gate electrode 69a is provided and the memory cell array region on which the stacked gate pattern 77, 61a and 59b is provided, thereby forming third and fourth impurity regions 81 and 83, respectively. The third and fourth impurity regions 81 and 83 can be formed with impurities and concentration the same as the second impurity region 79. Preferably, the third and fourth impurity regions 81 and 83 are formed in a way to implant impurities such as phosphorus (P) and arsenic (As) at a dose of 5.0E13-5.0E1 ions/cm² and at an energy of 40-60 KeV.

As a result, the peripheral circuit region has impurities implanted at a dose and an energy higher than that in forming the first impurity region 71, using the spacers 73a which has been formed along the sidewalls of the gate electrode 69a as a mask. Thus, a source/drain region of the peripheral circuit region is provided with the LDD structure including the first impurity region 71 which is formed by alignment along the sidewalls of the gate electrode 69a and the third impurity region 81 which is formed adjacent to the first impurity region 71 by alignment with the spacers 73a and deep doped with impurities of a higher concentration than the first impurity region 71. On the other hand, the memory cell array region has a source/drain region with a double diffused (DD) structure comprised of the second impurity region 79 and the fourth impurity region 83 which is deep doped with impurities of a higher concentration than the second impurity region 79 or impurities of the same conductive type and concentration as the second impurity region 79.

As an another example, when the steps of forming the second photoresist pattern 75 and the second impurity region 79 are omitted, a source/drain region is formed with a single diffused (SD) structure including the fourth impurity region 83. Unless the fourth impurity region 83 is provided, the source/drain region is formed with the SD structure comprised of the second impurity region 79.

### SECOND EMBODIMENT

FIGS. 10A-10C are each sectional views of a non-volatile semiconductor memory device according to the present invention taken along lines a-a and b-b of FIG. 1 and c-c of FIG. 2 for explaining a second embodiment of a manufacturing method thereof. In concrete terms, the second embodiment for a manufacturing method of a non-volatile semiconductor memory device is the same as the first one in all aspects other than the manufacturing method for obtaining resultants of FIGS. 10A-10C.

Referring to FIGS. 10A-10C, a field insulating layer 53 is formed over a semiconductor substrate 51 to define an active region, and then a tunnel insulating layer 57 of 50-100 Å and a first conductive layer (not shown) of 1,000-1,500 Å such as a group V impurity doped polysilicon layer are sequentially provided over the entire surface of the semiconductor substrate 51 including memory cell array and peripheral circuit regions. Next, the first conductive layer is patterned to form a first conductive layer pattern 59a in the a-a direction (in the direction of the active region in FIG. 1) as shown in FIG. 10B. In this case, the first conductive layer formed on the peripheral circuit region is etched and removed. The tunnel insulating layer 57 is formed of an oxide layer or a composite layer including oxide and nitride layers.

A first insulating layer 61 such as oxide-nitride-oxide (ONO) layer is formed over the entire surface of the semiconductor substrate 51 including the memory cell array region on which the first conductive layer pattern 59a is formed and the peripheral circuit region. Then, a gate insulating layer 58 having a thickness of 100-300 Å is provided over the peripheral circuit region from which the first insulating layer 61 and the tunnel insulating layer 57 have been removed. The gate insulating layer 58 is formed of an oxide layer or a composite layer including oxide and nitride layers. Next, a second conductive layer 69, i.e., a second polysilicon layer 63 of 1,000-1,500 Å with which V group impurities are doped and a silicide layer 65 of 1,000-2,000 Å such as a tungsten silicide layer are sequentially formed on the first insulating layer 61 of the memory cell array region and the gate insulating layer 58 of the peripheral circuit region, respectively. The subsequent fabrication process proceeds in the same manner as the first preferred embodiment.

As described in the foregoing, since a non-volatile semiconductor memory device forms spacers only on the peripheral circuit region, a field insulating layer of the memory cell array region is not overetched during a dry etching for forming spacers, which can improve the insulation characteristic between unit devices thereof. Further, since the field insulating layer is not overetched, impurities does not permeate the lower part thereof during ion implantation for forming a source/drain region, which alleviates a problem on occurrence of an electrical short between active regions that a conventional non-volatile semiconductor memory device has.

While this invention has been particularly shown and described with references to preferred embodiments thereof, it will be understood by those skilled in the art that various changes in form and details may be made therein without departing from the spirit and scope of the invention as defined by the following claims.

What is claimed is:

1. A non-volatile semiconductor memory device, comprising:
a memory cell array region including a cell transistor capable of storing and erasing data, the cell transistor comprising a stacked gate pattern in which a floating gate, an interlayer insulating layer and a control gate are sequentially provided over a semiconductor substrate underlying a tunnel insulating layer, and a source/drain region of a single diffused structure including a first impurity region which is aligned along the sidewalls of the stacked gate pattern and formed in the vicinity of the surface of the semiconductor substrate; and
a peripheral circuit region including a transistor for driving the memory cell array region;
wherein the transistor of the peripheral circuit region comprises a gate insulating layer and a gate electrode overlying a semiconductor substrate, spacers formed along the sidewalls of the gate electrode, and a source/drain region of a lightly doped drain structure including a second impurity region which is aligned along the sidewalls of the gate electrode and formed in the vicinity of the surface of the semiconductor substrate and a third impurity region which is aligned on the spacers and deep doped with impurities of a higher concentration than that of the second impurity region.

2. The non-volatile semiconductor memory device of claim 1, wherein the spacers are comprised of one of an oxide layer and a nitride layer.

3. The non-volatile semiconductor memory device of claim 1, wherein the cell transistor comprises a source/drain region of a double diffused structure further including a fourth impurity region which is deep doped with impurities of a higher concentration than that of the first impurity region.

4. A method of manufacturing a non-volatile semiconductor memory device comprising:
forming a tunnel insulating layer on a memory cell array region of a semiconductor substrate over which a field insulating layer has been provided;
forming a first conductive layer pattern on the tunnel insulating layer and the field insulating layer;
forming an insulating layer over the first conductive layer pattern;
forming a gate insulating layer over the semiconductor substrate of the peripheral circuit region;
forming a second conductive layer on the insulating layer and the gate insulating layer;
patterning the second conductive layer of the peripheral circuit region to form a gate electrode;
forming a first impurity region aligned on the sidewalls of the gate electrode, in the vicinity of the surface of the semiconductor substrate;
forming spacers along the sidewalls of the gate electrode in the peripheral circuit region;
patterning the second conductive layer, the insulating layer and the first conductive layer pattern of the memory cell array region to form a stacked gate pattern in which a floating gate, an interlayer insulating layer, and a control gate are sequentially stacked;
providing a second impurity region which is aligned on the sidewalls of the stacked gate pattern and formed in the vicinity of the surface of the semiconductor substrate to form a source/drain region of a single diffused structure; and
providing a third impurity region which is aligned with the spacers of the peripheral circuit region and deep doped with impurities of a higher concentration than the concentration of the first impurity region to form a source/drain region of a lightly doped drain structure.

5. The method of claim 4, further comprising forming a fourth impurity region which is deep doped with impurities of a higher concentration than that of the second impurity region of the memory cell array region.

6. The method of claim 5, wherein the fourth impurity region is formed with the same impurities and concentration as the third impurity region.

7. The method of claim 4, wherein the third impurity region is formed with the same impurities and concentration as the second impurity reg on.

8. The method of claim 4, wherein the first impurity region is formed by implanting one of phosphorus and arsenic at a dose of 1.0×10¹³ to 3.0×10¹³ ions/cm² and at an energy of 30 to 50 KeV.

9. The method of claim 4, wherein the second impurity region is formed by implanting one of phosphorus and arsenic at a dose of 5.0×10¹² to 5.0×10¹³ ions/cm² and at an energy of 30 to 50 KeV.

10. The method of claim 4, wherein the third and fourth impurity regions are formed by implanting one of phosphorus and arsenic at a dose of 5.0×10¹³ to 5.0×10¹⁵ ions/cm² and at an energy of 40 to 60 KeV.

11. The method of claim 4, wherein the first conductive layer pattern is formed of a polysilicon layer.

12. The method of claim 4, wherein the second conductive layer is formed of a bilayer including polysilicon and tungsten silicide layers.

13. The method of claim 4, wherein the insulating layer is formed of an oxide-nitride-oxide layer.

14. A method of manufacturing a non-volatile semiconductor memory device comprising:
forming a tunnel insulating layer and a first conductive layer sequentially on memory cell array region and a peripheral circuit region of a semiconductor substrate over which a field insulating layer has been provided;
patterning the first conductive layer to form a first conductive layer pattern over the tunnel insulating layer and the field insulating layer of the memory cell array region;
forming an insulating layer over of the first conductive layer pattern;
forming a gate insulating layer over the semiconductor substrate of the peripheral circuit region;
forming a second conductive layer over the insulating layer and gate insulating layer;
patterning the second conductive layer of the peripheral circuit region to form a gate electrode;
forming a first impurity region aligned along the sidewalls of the gate electrode in the vicinity of the surface of the semiconductor substrate;
forming spacers along the sidewalls of the gate electrode of the peripheral circuit region;
patterning the second conductive layer, the insulating layer and the first conductive layer pattern of the memory cell array region to form a stacked gate pattern in which a floating gate, an interlayer insulating layer and a control gate are sequentially stacked;
providing a second impurity region aligned along the sidewalls of the stacked gate pattern in the vicinity of the surface of the semiconductor substrate to form a source/drain region of a single diffused structure; and
providing a third impurity region which is aligned with the spacers of the peripheral circuit region and deep doped with impurities of a higher concentration than the concentration of the first impurity region to form a source/drain region of a lightly doped drain structure.

15. The method of claim 14, wherein the memory cell array region comprises a source/drain region of a double diffused structure by further forming a fourth impurity region which is deeply doped with impurities of a higher concentration than the second impurity region.

16. The method of claim 15, wherein the fourth impurity region is formed with the same impurities and concentration as the third impurity region.

17. The method of claim 14, wherein the third impurity region is formed with the same impurities and concentration as the second impurity region.

18. A non-volatile semiconductor memory device, comprising:
a memory cell array region including a cell transistor capable of storing and erasing data, the cell transistor comprising a stacked gate pattern in which a floating gate, an interlayer insulating layer and a control gate are sequentially provided over a semiconductor substrate underlying a tunnel insulating layer, and a source/drain region of a double diffused structure including a first impurity region which is aligned along the sidewalls of the stacked gate pattern and a second impurity region which is deeply doped with impurities of the same conductive type as the impurities of the first impurity region, formed in the vicinity of the surface of the semiconductor substrate; and
a peripheral circuit region including a transistor for driving the memory cell array region;
wherein the transistor of the peripheral circuit region comprises a gate insulating layer and a gate electrode overlying a semiconductor substrate, spacers formed along the sidewalls of the gate electrode, and a source/drain region of a lightly doped drain structure including a third impurity region which is aligned along the sidewalls of the gate electrode and formed in the vicinity of the surface of the semiconductor substrate and a fourth impurity region which is aligned on the spacers and deep doped with impurities of a higher concentration than that of the third impurity region.

19. The non-volatile semiconductor memory device of claim 18, wherein the impurity concentration of the second impurity region is higher than that of the first impurity region.

20. The non-volatile semiconductor memory device of claim 18, wherein the impurity concentration of the second impurity region is the same as that of the first impurity region.
